(19) United States
(12) Patent Application Publication
(10) Pub. No.: US 2012/0153473 A1
(43) Pub. Date: Jun. 21, 2012

(54) LEAD PIN FOR PACKAGE SUBSTRATE AND SEMICONDUCTOR PACKAGE PRINTED CIRCUIT BOARD INCLUDING THE SAME

(75) Inventor: Sang Yul LEE, Busan (KR)

(73) Assignee: SAMSUNG ELECTRO-MECHANICS CO., LTD., Gyunggi-do (KR)

(21) Appl. No.: 13/046,396

(22) Filed: Mar. 11, 2011

(30) Foreign Application Priority Data
Dec. 20, 2010 (KR) 10-2010-0130993

(51) Int. Cl. H01L 23/49; H01B 5/00

(52) U.S. Cl. 257/739; 174/126.3; 257/E23.024

(57) ABSTRACT

Disclosed herein is a lead pin for a package substrate including a connection pin, and a head part including a flange part formed at one end of the connection pin and having one surface bonded to the connection pin and a flat part formed at the other surface of the flange part and having at least one groove formed along an outer circumference thereof. According to the present invention, the grooves are formed along the outer circumference of the flat part of the head part of the lead pin to increase a bonding area, thereby making it possible to increase bonding strength of the lead pin.

### CROSS REFERENCE TO RELATED APPLICATION

This application claims the benefit of Korean Patent Application No. 10-2010-0130993, filed on Dec. 20, 2010, entitled “Lead Pin For Package Substrate And Semiconductor Package Printed Circuit Board Including The Same”, which is hereby incorporated by reference in its entirety into this application.

### BACKGROUND OF THE INVENTION

1. Technical Field

The present invention relates to a lead pin for a package substrate and a semiconductor package printed circuit board including the same.

2. Description of the Related Art

With the development of electronics industry, various types of semiconductor packages have been manufactured. Recently, as the wiring density of a semiconductor package is increased, a semiconductor package substrate in a Pin Grid Array (PGA) type in which a plurality of T-type lead pins are mounted has been widely used as a substrate that connects a package substrate on which an integrated circuit (IC) is mounted to a main board.

In a general package substrate, a pin insert type that a pin is inserted through a hole and a T-type lead pin that is attached to a package substrate by soldering have been mainly used. The T-type lead pin has gradually become widespread due to minimal limitations on the circuit configuration of the package substrate compared to the pin insert type.

FIG. 1 is a cross-sectional view showing a bonding state of a connection pad and a lead pin according to a prior art. As shown in FIG. 1, after soldering, for example, solder paste 300 is applied to a connection pad 200, a head part 100a of a lead pin 100 is mounted on the connection pad 200 to contact therewith. Thereafter, the solder paste 300 is melted by a reflow process in a state in which the lead pin 100 is mounted on the connection pad 200, such that the lead pin 100 is bonded to the connection pad 200.

As shown in FIG. 1, the head part 100a of the lead pin 100 has a semi-circular shape in the prior art, thereby causing a problem that the bonding strength of the lead pin 100 is degraded. In particular, in the case of the Pin Grid Array (PGA) type in which the lead pin 100 is mounted on the back surface of the substrate, excessive warpage of the substrate is generated after the pin is mounted thereon, causing problems in that yield of a socket mounting is degrade, pin bonding strength is degraded, and bonding reliability of the pin is degraded due to the degradation of the bonding strength at the time of a bonding process.

### SUMMARY OF THE INVENTION

The present invention has been made in an effort to provide a lead pin for a package substrate increasing a bonding area of a head part of the lead pin for a package substrate and improving operation reliability of the package substrate at the time of bonding, and a semiconductor package printed circuit board including the lead pin for a package substrate.

According to a preferred embodiment of the present invention, there is provided a lead pin for a package substrate including: a connection pin; and a head part including a flange part formed at one end of the connection pin and having one surface bonded to the connection pin, and a flat part formed at the other surface of the flange part and having at least one groove formed along an outer circumference thereof.

The grooves may be consecutively formed along the outer circumference of the flat part.

An inner surface of the groove may be formed with roughness.

The groove may be formed to be inwardly concave.

According to another preferred embodiment of the present invention, there is provided a lead pin for a package substrate including: a connection pin; a head part including a flange part and a flat part; and a guide dam formed along an outer circumference of one surface of the flange part to which the connection pin is bonded and further protruding as compared to one surface of the flange part.

According to another preferred embodiment of the present invention, there is provided a semiconductor package substrate including a lead pin for a package substrate, including: a substrate formed with a connection pad; a lead pin including a connection pin, and a head part including a flange part formed at one end of the connection pin and having one surface bonded to the connection pin, and a flat part formed at the other surface of the flange part and having at least one groove formed along an outer circumference thereof; and solder bonding the connection pad of the substrate to the head part of the lead pin.

The grooves may be consecutively formed along the outer circumference of the flat part.

An inner surface of the groove may be formed with roughness.

The semiconductor package substrate may further include a guide dam formed along an outer circumference of one surface of the flange part to which the connection pin is bonded and further protruding as compared to one surface of the flange part.

The groove may be formed to be inwardly concave.

### BRIEF DESCRIPTION OF THE DRAWINGS

FIG. 1 is a cross-sectional view showing a bonding state of a connection pad and a lead pin according to a prior art;

FIG. 2 is a cross-sectional view of a lead pin for a package substrate according to the present invention;

FIG. 3 is a view showing a bonding state of the lead pin for a package substrate of FIG. 2;

FIG. 4 is a cross-sectional view of a lead pin for a package substrate according to another embodiment of the present invention; and

FIG. 5 is a view showing a bonding state of the lead pin for a package substrate of FIG. 4.

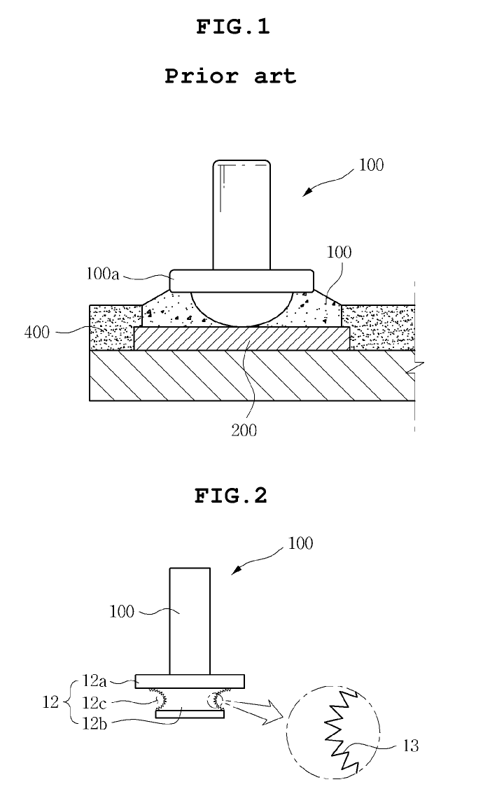

### DESCRIPTION OF THE PREFERRED EMBODIMENTS

Various features and advantages of the present invention will be more obvious from the following description with reference to the accompanying drawings.

The terms and words used in the present specification and claims should not be interpreted as being limited to typical meanings or dictionary definitions, but should be interpreted as having meanings and concepts relevant to the technical scope of the present invention based on the rule according to which an inventor can appropriately define the concept of the tem to describe most appropriately the best method he or she knows for carrying out the invention.

The above and other objects, features and advantages of the present invention will be more clearly understood from the following detailed description taken in conjunction with the accompanying drawings. In the specification, in adding reference numerals to components throughout the drawings, it is to be noted that like reference numerals designate like components even though components are shown in different drawings. Further, when it is determined that the detailed description of the known art related to the present invention may obscure the gist of the present invention, a detailed description thereof will be omitted.

Hereinafter, preferred embodiments of the present invention will be described in detail with reference to the accompanying drawings.

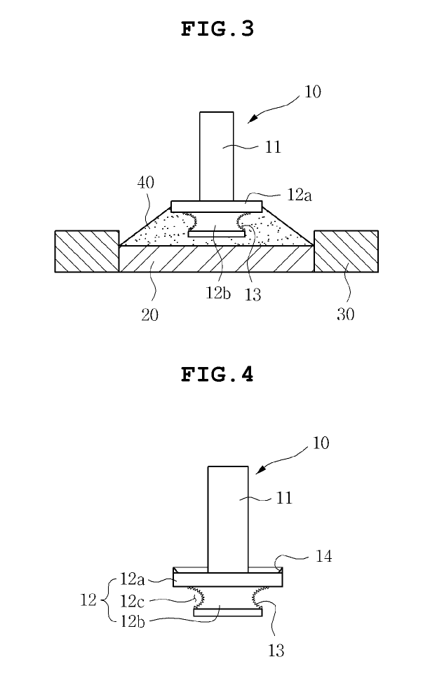

FIG. 2 is a cross-sectional view of a lead pin for a package substrate according to the present invention, and FIG. 3 is a view showing a bonding state of the lead pin for a package substrate of FIG. 2. A lead pin 10 for a package substrate according to the present invention is configured to include a connection pin 11, and a head part 12 including a flange part 12a formed at one end of the connection pin 11 and having one surface bonded to the connection pin 11, and a flat part 12b formed at the other surface of the flange part 12a and having at least one groove 12c formed along an outer circumference thereof.

The connection pin 11, which is used to bond an IC chip in the PGA substrate, is bonded to the connection pad 20 of the package substrate using a material having a high melting point. Although the connection pin 11 is generally formed to have a cylindrical shape, the shape thereof is not limited thereto, but it may also be formed to have various polygonal shapes. The connection pin 11 may be formed to have a predetermined height depending on circuit components.

The head part 12 is configured to include the flange part 12a and the flat part 12b. The flange part 12a has one surface to which the connection pin 11 is bonded, wherein one surface may have a diameter larger than that of a surface to which the connection pin 11 is bonded. The flange part 12a has the other surface to which the flat part 12b is bonded. The flat part 12b is a portion which is bonded to solder 40 when the lead pin 10 is bonded to the substrate. The shape of the flat part 12b has an influence on the strength when the lead pin 10 is bonded to the substrate and mounting force when the lead pin 10 is mounted with a socket or the like. The flat part 12b has grooves 12c formed along an outer circumference thereof in a vertical direction to a direction that the lead pin 10 is bonded. The grooves 12c are formed and the grooves 12c are filled with the bonded solder 40, such that a bonding area is further increased and bonding force is also increased. Although at least one groove 12c, which is formed along the outer circumference of the flat part 12b, may be partially formed inwardly of the outer circumference thereof, it is not limited thereto but may also be consecutively formed along the outer circumference thereof in a donut shape. The solder 40 is inserted and bonded to the grooves 12c inwardly formed along the outer circumference of the flat part 12b, such that the lead pin 10 is not slanted and the bonding thereof is not separated. The groove 12c of the flat part 12b may be formed to be inwardly concave. The shape of the groove 12c inwardly formed is not limited thereto but may have various shapes. The grooves 12c are formed in a vertical direction to a direction that the lead pin 10 is bonded, such that the lead pin 10 can be more strongly bonded to the solder 40.

An inner surface of the groove 12c inwardly formed along the outer circumference of the flat part 12b may be formed with roughness 13. The roughness 13 is formed in the inner surface of the groove 12c to increase the bonding area with the solder 40, thereby making it possible to improve bonding force of the lead pin 10.

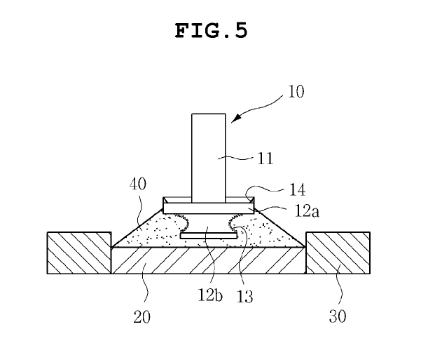

FIG. 4 is a cross-sectional view of a lead pin for a package substrate according to another embodiment of the present invention, and FIG. 5 is a view showing a bonding state of the lead pin for a package substrate of FIG. 4.

Hereinafter, an explanation of a connection pin 11 and a head part 12 including a flange part 12a and a flat part 12b of a lead pin 10 according to another embodiment of the present invention overlapping those of the lead pin 10 for a package substrate according to an embodiment of the present invention as described above will be omitted.

The lead pin 10 for a package substrate according to another embodiment of the present invention may further includes a guide dam 14 formed on the flange part 12a of the head part 12. The guide dam 14 may be formed to protrude along an outer circumference of a surface of the flange part 12a to which a connection pin 11 is bonded. When the flat part 12b formed on the other surface of the flange part 12a is bonded with solder 40, the guide dam 14 can prevent the solder 40 from climbing to the flange part 12a. The height of the guide dam 14 is not particularly limited but is formed to be higher than that of a surface to which the connection pin 11 of the flange part 12a is bonded, thereby making it possible to prevent the solder 40 from climbing. The guide dam 14 may be formed at edges of the flange part 12a, while having the same shape as the outer circumference of the flange part 12a, and the shape thereof is not particularly limited, if it can prevent the solder 40 from climbing. For example, the guide dam 14 may be formed to have a barrier rib such as a partition so as to prevent the solder 40 from climbing and a climbing prevention projection for preventing the solder 40 from climbing may also additionally be inwardly or outwardly formed on the upper portion of the barrier rib.

A semiconductor package printed circuit board including the lead pin 10 for a package substrate according to the present invention may be configured to include a substrate formed with a connection pad 20, the lead pin 10 for a package substrate including a connection pin 11 and a head part 12 including a flange part 12a formed at one end of the connection pin 11 and having one surface bonded to the connection pin 11 and a flat part 12b formed on the other surface of the flange part 12a and having at least one groove 12c formed along the outer circumference thereof, and solder 40 bonding the connection pad 20 of the substrate to the head part 12 of the lead pin 10.

The lead pin 10 is bonded to the substrate formed with the connection pad 20. The connection pad 20 serves to electrically interconnect wire patterns of the package substrate with circuit components. The solder 40, which is printed to the connection pad 20, is brown solder balls having viscosity and resin mass. The solder 40 itself may be made of an alloy of lead, zinc, and silver but the material thereof is not always limited thereto. The solder 40 printed to the connection pad 20 of the package substrate is subjected to a reflow process in which the solder 40 is melted through heat treatment, thereby making it possible to bond and fix the lead pin 10.

The lead pin 10 for a package substrate is configured to include the connection pin 11, and the head part 12 including the flange part 12a formed at one end of the connection pin 11 and having one surface bonded to the connection pin 11, and the flat part 12b formed at the other surface of the flange part 12a and having at least one groove 12c formed along an outer circumference thereof. In this configuration, the grooves 12c formed in the flat part 12b are consecutively formed along the outer circumference of the flat part 12b, wherein inner surface of the groove 12c may further be formed with roughness 13.

In addition, the groove 12 may be formed to be inwardly concave but the shape of the groove 12c is not always limited thereto and may have various shapes that are concave inwardly.

In addition, the lead pin 10 for a package substrate may additionally be provided with a guide dam 14 formed along an outer circumference of one surface of the flange part 12a to which the connection pin 11 is bonded and further protruding as compared to one surface of the flange part 12a.

The solder 40 bonds the connection pad 20 of the substrate to the head part 12 of the lead pin 10. In this configuration, the solder 40 is brown solder balls having viscosity and resin mass. The solder 40 itself may be made of an alloy of lead, zinc, and silver but the material thereof is not always limited thereto.

The present invention overlaps the description of the lead pin 10 for a package substrate according to the present invention and thus, a detailed description thereof will be omitted.

According to the present invention, the grooves are formed along the outer circumference of the flat part of the head part of the lead pin to increase a bonding area, thereby making it possible to increase bonding strength of the lead pin.

In addition, the grooves formed at the flat part of the head part of the lead pin are filled with the solder to strengthen bonding force between the solder and the lead pin, thereby making it possible to increase bonding force of the lead pin.

In addition, the inner surface of the groove formed at the flat part of the head part of the lead pin is formed with roughness, thereby making it possible to improve bonding force of the lead pin.

In addition, the guide dam is formed at outer side of one surface of the flange part of the head part of the lead pin to prevent the solder from climbing, thereby making it possible to improve reliability of the package substrate bonded by the lead pin.

Although the preferred embodiments of the present invention have been disclosed for illustrative purposes, they are for specifically explaining the present invention and thus a lead pin for a package substrate and a semiconductor package printed circuit board including the same according to the present invention are not limited thereto, but those skilled in the art will appreciate that various modifications, additions and substitutions are possible, without departing from the scope and spirit of the invention as disclosed in the accompanying claims.

Accordingly, such modifications, additions and substitutions should also be understood to fall within the scope of the present invention.

What is claimed is:

1. A lead pin for a package substrate comprising:
a connection pin; and
a head part including a flange part formed at one end of the connection pin and having one surface bonded to the connection pin, and a flat part formed at the other surface of the flange part and having at least one groove formed along an outer circumference thereof.

2. The lead pin for a package substrate as set forth in claim 1, wherein the grooves are to consecutively formed along the outer circumference of the flat part.

3. The lead pin for a package substrate as set forth in claim 1, wherein an inner surface of the groove is formed with roughness.

4. The lead pin for a package substrate as set forth in claim 1, further comprising a guide dam formed along an outer circumference of one surface of the flange part to which the connection pin is bonded and further protruding as compared to one surface of the flange part.

5. The lead pin for a package substrate as set forth in claim 1, wherein the groove is formed to be inwardly concave.

6. A semiconductor package substrate comprising:
a substrate formed with a connection pad;
a lead pin for a package substrate including a connection pin, and a head part including a flange part formed at one end of the connection pin and having one surface bonded to the connection pin and a flat part formed at the other surface of the flange part and having at least one groove formed along an outer circumference thereof; and
solder bonding the connection pad of the substrate to the head part of the lead pin.

7. The semiconductor package substrate as set forth in claim 6, wherein the grooves are consecutively formed along the outer circumference of the flat part.

8. The semiconductor package substrate as set forth in claim 6, wherein an inner surface of the groove is formed with roughness.

9. The semiconductor package substrate as set forth in claim 6, further comprising a guide dam formed along an outer circumference of one surface of the flange part to which the connection pin is bonded and further protruding as compared to one surface of the flange part.

10. The semiconductor package substrate as set forth in claim 6, wherein the groove is formed to be inwardly concave.
